(19) United States
(12) Patent Application Publication
(10) Pub. No.: US 2009/0008712 A1
(43) Pub. Date: Jan. 8, 2009

(54) CARBON NANO-TUBE (CNT) THIN FILM COMPRISING METALLIC NANO-PARTICLES, AND A MANUFACTURING METHOD THEREOF

(75) Inventors: Seong Jae CHOI, Seoul (KR); Hyeon Jin SHIN, Suwon-si (KR); Seonmi YOON, Yongin-si (KR); In Yong SONG, Suwon-si (KR); Jaeyoung CHOI, Suwon-si (KR)

Correspondence Address: CANTOR COLBURN, LLP, 20 Church Street, 22nd Floor, Hartford, CT, 06103, US

(73) Assignee: SAMUSUNG ELECTRONICS, CO., LTD., Suwon-si (KR)

(21) Appl. No.: 12/060,902

(22) Filed: Apr. 2, 2008

(30) Foreign Application Priority Data
Jun. 22, 2007 (KR) 10-2007-0061702

(51) Int. Cl. H01L 29/786; H01B 1/04; B05D 5/12

(52) U.S. Cl. 257/347; 252/503; 427/77; 257/E29.273; 977/742; 977/936

(57) ABSTRACT

Disclosed is a carbon nanotube (CNT) thin film having metallic nanoparticles. The CNT thin film includes a plastic transparent substrate and a CNT composition coated on the substrate. The CNT composition includes a CNT and metallic nanoparticles distributed on the CNT surface. The plastic transparent substrate is flexible. The metallic nanoparticles are formed by heating a metallic precursor adsorbed in the CNT surface. A method of manufacturing the CNT thin film having metallic nanoparticles is also disclosed. A CNT-dispersed solution is prepared by mixing a CNT with a dispersant or a dispersion solvent. The CNT-dispersed solution is used to form a CNT thin film. Metallic precursors are implanted in the CNT thin film. Then, a heat-treatment is applied to transform the metallic precursors into metallic particles including metallic nanoparticles.

This application claims priority to Korean Patent Application Number 10-2007-0061702, filed on Jun. 22, 2007, and all the benefits accruing therefrom under 35 U.S.C. §119, the contents of which are hereby incorporated by reference in its entirety.

### BACKGROUND OF THE INVENTION

The disclosure relates to a carbon nanotube thin film comprising metallic nanoparticles and a method of manufacturing the same.

A display device uses a transparent electrode that is optically transparent and electrically conductive. At present, an indium tin oxide (ITO) is most commonly used as the transparent electrode. However, the steady increase in ITO consumption has come to increase the price thereof. Further an electrode formed of ITO material tends to cause cracks when it is bent. These cracks lead to an increase in the resistance of the electrode.

Therefore, it is necessary to develop a transparent electrode material that can be more safely applied to flexible electronic devices. One of materials that has recently generated interests is a carbon nanotube (CNT) material. This CNT material has an excellent electroconductivity and strength while it can be easily bent. Thus, the CNT material can be used to form a flexible transparent electrode, which can be extensively applied to display devices such as traditional LCDs, OLEDs, and paper-like displays. Further, it can be employed as an electrode material for energy storage devices such as solar cells and secondary cells.

In case of CNT transparent electrodes, the electroconductivity, transparency and flexibility thereof, among others, of great importance. In general, CNT transparent electrodes are manufactured by dispersing a CNT powder into a dispersant solution to prepare a CNT ink, and coating or applying the CNT ink on a plastic substrate. In order to improve the electroconductivity of the CNT transparent electrode, it is desirable is to ensure that a carrier is able to move within the CNT itself and also to travel freely between CNTs.

It has been recently disclosed that: if a transparent electrode contains a large amount of CNT to make contact with each other, that is, if the amount of CNT is higher than a percolation threshold, the resistance of the CNT network film forming the electrode is governed mostly by the contact resistance between the CNTs, not by the CNT resistance itself.

Therefore, CNT network formation and reduction in the contact resistance between CNTs within the CNT network are useful factors to improving the electroconductivity of a CNT transparent electrode. However, CNTs are initially synthesized in a powder form where numerous CNT bundles are aggregated by van der Waals forces, so the aggregated CNT bundles are to be dispersed to form the CNT network.

Various dispersants have been developed and used for dispersing CNT bundles to facilitate formation of the network structure, but the resistance of the dispersants itself tends to increase the contact resistance between CNTs and consequently to increase the resistance of the transparent electrode.

### SUMMARY OF THE INVENTION

Electroconductivity of a flexible transparent CNT electrode can be improved by forming metal nanoparticles in the CNT thin film of the electrode.

That is, a CNT is first dispersed in a dispersant solution to prepare a CNT-dispersed solution, and the CNT-dispersed solution is applied onto a plastic substrate to manufacture a CNT thin film. Here, the plastic substrate includes a flexible transparent substrate. The CNT thin film is then heated at a temperature that does not deteriorate the plastic substrate, and through this heat treatment metal nanoparticles are uniformly formed in the CNT thin film, which serves to improve electroconductivity of an electrode formed using the CNT thin film.

Disclosed is a carbon nano-tube (CNT) composition, which includes a CNT, and a metallic precursor capable of being transformed into a metal nanoparticle through a heat treatment. The CNT composition may further comprise a CNT dispersant. The metallic precursor is bonded onto the CNT surface. The metallic precursor contains at least one metallic element selected from the group consisting of Ag, Au, Cu, Pt and Pd. The heat-treatment is performed at a temperature lower than 200° C.

Disclosed is a CNT thin film. The CNT thin film includes a plastic substrate, and a CNT composition being coated on the plastic substrate. The plastic substrate includes a flexible and/or transparent substrate. The CNT composition comprises a CNT, and metallic nanoparticles being distributed on the CNT surface by heat treatment.

Further disclosed is a method of manufacturing a CNT thin film. A CNT-dispersed solution is prepared by mixing a CNT with a dispersant or a dispersion solvent. The CNT-dispersed solution is used to form a CNT thin film. Metallic precursors are implanted in the CNT thin film. Then, a heat-treatment is applied to transform the metallic precursors into metallic particles including metallic nanoparticles.

The CNT-dispersed solution can be prepared by mixing a CNT with a dispersant or a dispersion solvent. The CNT thin film can be formed by filtering the CNT-dispersed solution through a porous membrane (as an alumina membrane) and transferring the CNT thin film on a substrate. The substrate includes a plastic film or a transparent plastic film. The metallic precursors can be implemented into the CNT thin film by passing or filtering a metallic precursor solution through the CNT thin film formed on the porous membrane, or by immersing the CNT thin film in a metallic precursor solution. In this way, metallic precursors can be adsorbed on the CNT surface.

In order to form a CNT thin film, the CNT-dispersed solution can be coated directly on a substrate, without filtering the solution.

The metallic precursors can be added to the CNT-dispersed solution before forming a CNT thin film.

The CNT thin film having metallic nanoparticles can be used for fabricating various electronic devices such as flexible transparent electrodes, thin film transistors and the like.

### BRIEF DESCRIPTION OF THE DRAWINGS

FIG. 1 diagrammatically shows transformation of metallic precursors into metallic nanoparticles through a heat-treatment;

FIG. 2 diagrammatically shows a metallic precursor being bonded onto a CNT surface through a charge-transfer;

FIG. 3 schematically shows a process for manufacturing a CNT thin film;

FIG. 4 schematically shows an alternative process for manufacturing a CNT thin film;

FIG. 5 is a graph showing Raman spectra in the RBM range for a CNT thin film having metallic nanoparticles;

FIG. 6 is a graph showing G-band Raman spectra including a BWF curve for a CNT thin film having metallic nanoparticles; and

FIG. 7 is photographs for a CNT thin film before and after a heat treatment.

### DESCRIPTION OF EXEMPLARY EMBODIMENTS

Hereinafter, exemplary embodiments will be set forth in detail with reference to the accompanying drawings

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but are included to identify individual elements. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements and the thicknesses of layer and regions are exaggerated for clarity.

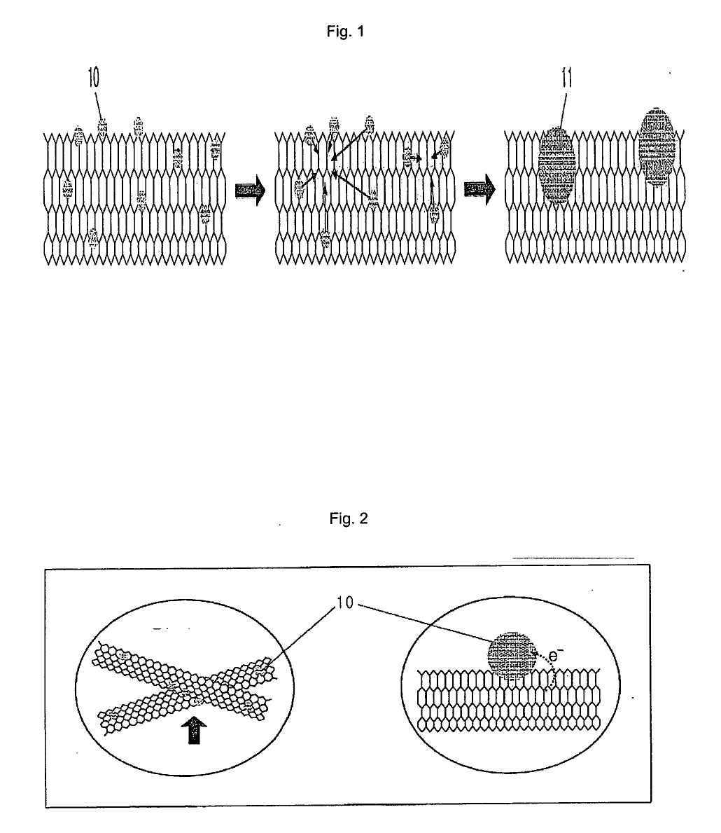

FIG. 1 diagrammatically shows transformation of metallic precursors into metallic nanoparticles through a heat treatment according to an embodiment of the present invention. Referring to FIG. 1, metallic precursors 10 are adsorbed on a CNT surface and transformed into metallic nanoparticles 11 through a heat treatment. In this embodiment, the heat treatment is carried out at a temperature of lower than 200° C. that would not deteriorate a plastic substrate supporting the CNTs. The metallic precursors 10 and metallic nanoparticles 11 contain at least one metallic element such as Ag, Au, Cu, Pt, Pd and the like.

FIG. 2 diagrammatically shows a metallic precursor for a metallic nanoparticle being bonded onto a CNT surface through charge-transfer. After the metallic precursor 10 of a metallic nanoparticle is bonded onto the CNT surface by charge-transferring, a heat treatment is performed to transform the metallic precursors into metallic nanoparticles uniformly on the CNT surface. Consequently, contact resistance between CNTs can be reduced due to the metallic nanoparticles. In addition, the charge-transfer, i.e., p-doping, also serves to lower the whole resistance of the CNT thin film holding the CNTs. Details on the reduction of resistance will be explained hereinafter.

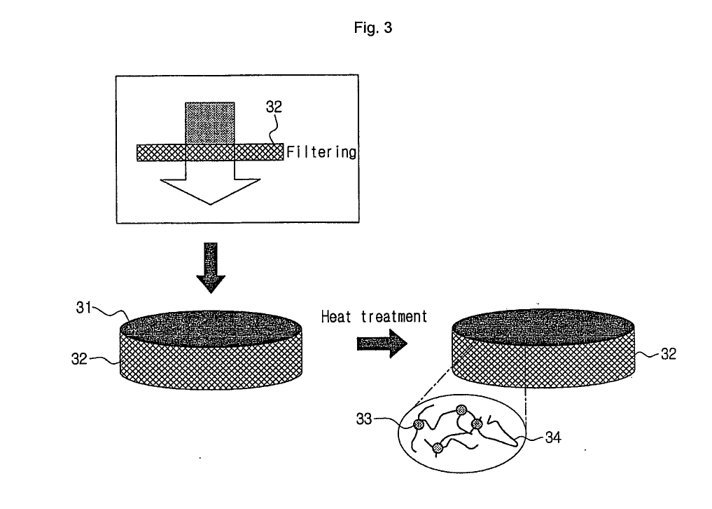

FIG. 3 schematically shows a process for manufacturing a CNT thin film comprising metallic nanoparticles according to an embodiment of the present invention. In this embodiment, a silver (Ag) precursor solution is employed as a metallic precursor for forming metallic nanoparticles. As shown in FIG. 3, first a CNT-dispersed solution is filtered to form a CNT thin film 31, and then a silver precursor solution is made to pass through the CNT this film 31, using a vacuum filtering system. The vacuum filtering system is a device which filters the CNT-dispersed solution or the silver precursor solution through the porous membrane 32, so as to allow the silver precursor to be adsorbed onto the CNTs 34. Through a heat treatment, the silver precursors are transformed into silver nanoparticles 33 uniformly throughout the CNT thin film 31. Hereafter, the procedures of FIG. 3 will be explained in further details.

First, in order to prepare a CNT-dispersed solution 30, 1 mg of single walled CNT (manufactured by SouthWest Nano Technologies, Inc.) is mixed with 10 mL of N-Methylpyrrolidone (‘NMP’) in a 20 mL glass bottle to form a CNT-NMP solution. The CNT-NMP solution is placed in an ultrasonic bath for 10 hours for sonification. The CNT-NMP solution is then poured into a 50 mL conical tube, and centrifuged for 10 minutes at 10,000 rpm. Following the centrifugation, the upper portion of the CNT-NMP solution that does not contain any precipitates is taken as a CNT-dispersed solution for subsequent processes.

Next, 2 mL of the CNT-dispersed solution is filtered using a vacuum filter system over an alumina membrane 32 (Anodisc, 200 nm) to form the CNT thin film 31. By filtering the CNT-dispersed solution, CNTs 34 remains on the alumina membrane 32 to form the CNT thin film 31 and solvent of the CNT-dispersed solution passes through the alumina membrane 32. The CNT thin film 31 is formed on the alumina membrane 32.

Then, a metallic precursor, e.g., a silver precursor solution is prepared. For this purpose, 0.85 g of silver nitrate and 0.74 mL of butylamine are mixed with 10 mL of toluene. A sonicator is used to facilitate dissolution of the mixture and form a silver precursor solution, and only the top portion of the solution is taken for use. Here, silver butylamine complex to be used in this embodiment is formed and silver butylamine complex is the top portion of the solution. Thus, only the top portion of the solution is taken for use.

The silver precursor solution is filtered using a vacuum filter system and allowed to pass through the CNT thin film 31 such that silver precursors are adsorbed onto the CNT thin film 31. The CNT thin film 31 formed on the alumina membrane 32 has many pores. Thus, in case of filtering the silver precursor solution through the CNT thin film 31 formed on the alumina membrane 32, the silver precursor solution passes through the pores such that the silver precursors are adsorbed onto the CNT surface due to electron affinity between the CNTs and the silver precursors. Here, the silver precursors are bonded onto the surface of the CNTs 34 forming the CNT thin film 31 by charge-transfer.

Following the adsorption of silver precursors onto the CNT surface, the CNT thin film 31 is subjected to a heat treatment. For example, the CNT thin film 31 is placed on a hot plate at controlled temperatures. Through this heat treatment, the adsorbed silver precursors are transformed into silver nanoparticles 33 of uniform size on the CNT thin film. The heat treatment is performed at a temperature lower than 200° C. to prevent degradation of the CNT thin film 31.

The above-prepared CNT thin film is transferred on a transparent substrate and used to fabricate a transparent electrode. Then, sheet resistance of the transparent electrode is measured using a sheet resistance meter. The sheet resistance before and after a heat treatment temperature were measured. The resistance measurement was performed against the transparent electrode fabricated from the CNT thin film. However, as the transparent electrode is the CNT thin film formed on a transparent substrate, resistance of the transparent electrode is a characteristic of the CNT thin film.

Table 1 shows the sheet resistances measured from the transparent electrode, i.e. the CNT thin films having the silver nanoparticles 33 as prepared above. Here, the heat treatment was carried out at 120° C. for 1 hour on each CNT thin film. Resistance of the CNT thin film was measured before the heat treatment, and after the heat treatment, i.e., after silver nanoparticles 33 were uniformly formed. Then, an average value per unit sheet surface was calculated.

TABLE 1

| | | | Average sheet |
|---|---|---|---|
| | 1st | 2nd | resistance (Ω/sq) |
| CNT/NMP | 55.62 | 53.47 | 54.55 |
| CNT/NMP → Silver nanoparticles | 16.15 | 14.49 | 15.32 |

As apparent from Table 1, the average resistance value of the CNT thin film is 54.55 Ω/sq before heating, but it is reduced to 15.32 Ω/sq after heating, i.e., after formation of silver nanoparticles. That is, it is can be seen that the resistance of the CNT thin film can be remarkably reduced by forming metallic nanoparticles through a heat treatment.

As can be seen from the above example, in case where silver nanoparticles are formed in a CNT thin film, the average sheet resistance thereof was decreased by about 72%. In other words, the resistance of a transparent electrode can be reduced by forming metallic nanoparticles throughout the CNT surface through heating.

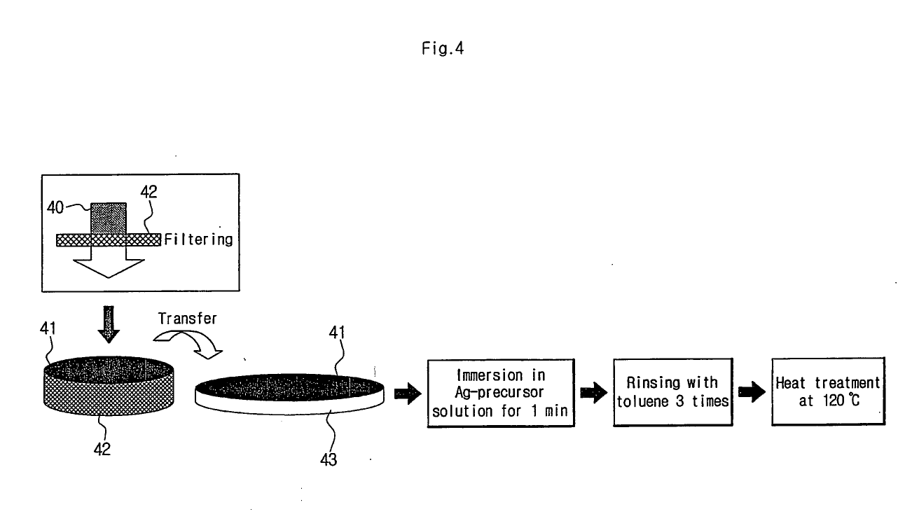

FIG. 4 schematically shows an alternative method of manufacturing a CNT thin film having silver (Ag) nanoparticles, according to an embodiment of the present invention. In this embodiment, a CNT thin film 41 is transferred onto a PET film 43 used as a plastic substrate. The transferred CNT thin film is immersed in a silver precursor solution, and heat-treated to form silver nanoparticles thereon.

Hereafter, the processes of FIG. 4 will be explained more specifically.

First, a CNT-dispersed solution 40 is prepared in a similar manner to the previous embodiment. That is, 1 mg of a single walled CNT (manufactured by SouthWest Nano Technologies, Inc.) is mixed with 10 mL of NMP in a 20 mL glass bottle to form a CNT-NMP solution. The CNT-NMP solution is placed in an ultrasonic bath for 10 hours for sonification. Then, the CNT-NMP solution is poured into a 50 mL conical tube, and centrifuged for 10 minutes at 10,000 rpm. Following the centrifugation, the CNT-NMP solution not having any precipitate is taken as a CNT-dispersed solution for subsequent processes.

Next, as shown in FIG. 4, 2 mL of the CNT-dispersed solution is filtered using a vacuum filter system over an alumina membrane 42 (Anodisc, 200 nm) to form a CNT thin film 41. Then, the CNT thin film 41 formed on the alumina membrane 42 is covered with a PET film 43 having a similar size to the CNT thin film, and is pressed at about 80° C. for about 5 minutes, such that the CNT thin film 41 can be transferred onto the PET film 43 when the latter is detached.

In a separate process, a silver precursor solution is prepared. Similar to the previous embodiment, 0.85 g of silver nitrate and 0.74 mL of butylamine are mixed with in 10 mL of toluene. A sonicator is used to facilitate dissolution of the mixture and form a silver precursor solution, and only the top portion of the solution is taken for use.

As shown in FIG. 4, the CNT thin film 41 disposed on the PET film 43 is immersed in this silver precursor solution for about 1 minute such that the silver precursors are adsorbed throughout the bulk of the CNT thin film 41, including the surface of individual CNTs. Then, the CNT thin film adsorbed with the silver precursor is rinsed with toluene for several times, for example three times. Here, the silver precursors may be bonded onto the surface of the CNTs by charge-transfer.

The CNT thin film 41 containing silver precursors adsorbed therein is heated. For example, the CNT thin film 41 is placed on a hot plate and heated at controlled temperatures. Through this heat treatment, silver precursors are transformed into silver nanoparticles of substantially uniform size on the surface of the CNT thin film. For example, the heat treatment is performed at a temperature lower than 200° C. to prevent degradation of the CNT thin film 41.

The above-prepared CNT thin film is used to fabricate a transparent electrode. Then, sheet resistance of the transparent electrode is measured using a sheet resistance meter. The sheet resistance before and after a heat treatment temperature were measured. Table 2 shows the sheet resistances measured from the CNT thin films having the silver nanoparticles as fabricated above. Here, heat treatment was carried out at about 120° C. for about 20 minutes and for additional 40 minutes. The resistance of each CNT thin film was measured at the initial states, after the p-doping, and before and after the heat treatment. Then, average values per unit sheet surface were calculated.

TABLE 2

| | | Immersed in Ag- | | |
|---|---|---|---|---|
| | | BA/toluene for 1 min, | | Heat treatment at |
| | Inital | and rinsed with toluene | Heat treatment at | 120° C. for |
| Ω/sq | resistance | three times | 120° C. for 20 min. | additional 40 min. |
| | 2319 | 1668 | 1075 | 860 |
| | 2390 | 1724 | 1136 | 800 |
| | 2177 | 1643 | 1057 | 813 |
| | 2221 | 1790 | 974 | 769 |
| | 2437 | 1821 | 1037 | 765 |
| Average | 2308.8 | 1729.2 | 1055.8 | 801 |
| Decrease rate, | | −25.1 | −54.27 | −65.29 |
| relative to initial | | | | |
| resistance (%) | | | | |

In Table 2, the average sheet resistance of the CNT thin film is 2308.8 Ω/sq at the initial state, and 1729.2 Ω/sq after it was immersed in the silver precursor solution and rinsed with toluene, i.e., after the p-doping. That is, the resistance has been decreased by about 25% after the p-doping, but without any heat treatment.

Referring to Table 2 again, the average sheet resistance of the CNT thin film is 1729.2 Ω/sq before the heat treatment, 1055.8 Ω/sq after the heat treatment for 20 minutes at 120° C., and 801 Ω/sq after an additional heat treatment for 40 minutes at the same temperature, respectively.

That is, the sheet resistance of the CNT thin film has been further decreased by the heat-treatments, in other words, by the silver nanoparticles formed in the CNT thin film through the heat-treatments. Furthermore, it can be seen that the resistance can be further reduced as the heat treatment continues for a longer period of time.

Therefore, it can be seen from Table 2 that the average sheet resistance can be decreased by about 65% through p-doping and heat treatment. In other words, the sheet resistance of a CNT thin film can be reduced through the p-doping and also the formation of metallic nanoparticles within the CNT thin film. The resistance of a transparent electrode formed of such CNT thin films can be decreased in the same manner.

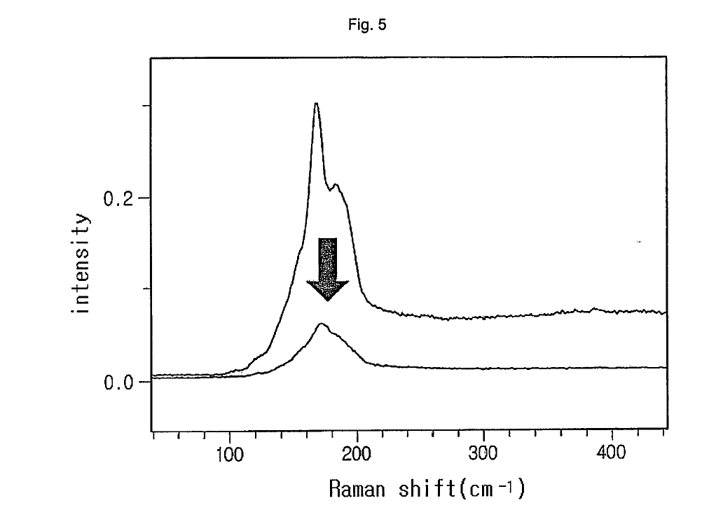

FIG. 5 is a graph showing Raman spectra at an excitation of 633 nm in the radial breathing mode (RBM) range for a CNT thin film having metallic nanoparticles. In the graph of FIG. 5, the intensity of the peak between 100 and 200 cm⁻¹ is sharply decreased, as indicated by the arrow. This means that something, i.e., metallic nanoparticles, is strongly adsorbed onto the CNT surface, and thus metallic nanoparticles were formed on the CNT surface.

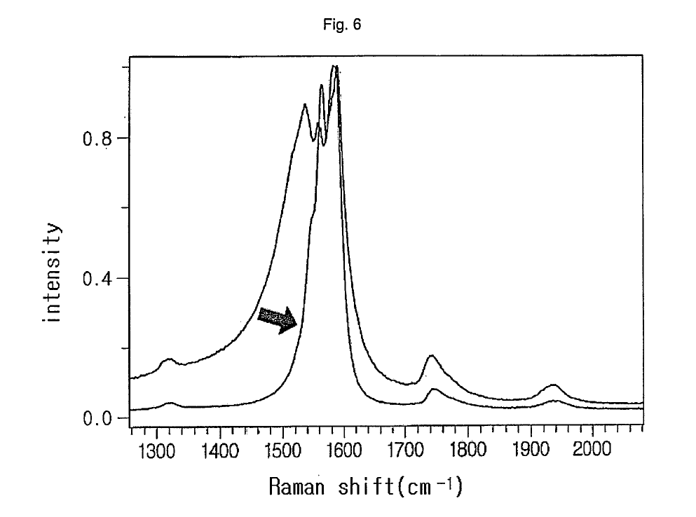

FIG. 6 is a graph showing G-band Raman spectra at an excitation of 633 nm including a BWF curve for a CNT thin film having metallic nanoparticles. In the graph of FIG. 6, the line width of BWF is decreased as indicated by the arrow. The decrease of BWF line width in Raman spectrum indicates that the CNT has lost electrons, in other words, has been oxidized by p-doing with the silver precursors through charge-transferring.

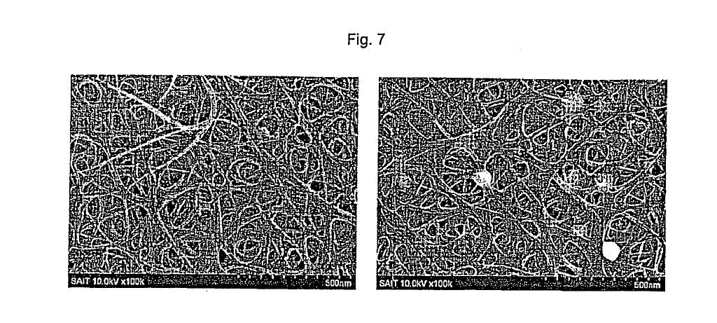

FIG. 7 is photographs for a CNT thin film before and after a heat treatment. In FIG. 7, the white dots in the right photograph indicate silver nanoparticles formed on the CNT surface of the CNT thin film through the heat treatment.

As described above, the silver precursor solution infiltrates into the CNT thin film, and silver nanoparticles are then uniformly formed in the CNT thin film through the heat treatment at a temperature lower than 200° C. Before heating, the CNT thin film is strongly doped with silver precursors, and exhibits a decrease in the resistance by about 25% through the p-doping. After the heating, the CNT thin film formed with silver nanoparticles exhibits a further reduction in the resistance up to about 65%.

That is, the CNT thin film having metallic nanoparticles formed evenly on the CNT surface can be used for fabricating flexible transparent electrodes providing for a reduced resistance. This CNT thin film containing such metallic nanoparticles can be applied to a variety of other fields including sensors, memories, electric cells, and the like.

While the present invention has been described with respect to the specific embodiments, it will be apparent to those skilled in the art that various changes and modifications may be made without departing from the spirit and scope of the invention as defined in the following claims.

In addition, many modifications can be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims. Moreover, the use of the terms first, second, etc. do not denote any order or importance, but rather the terms first, second, etc. are used to distinguished one element from another. Furthermore, the use of the terms a, an, etc. do not denote a limitation of quantity, but rather denote the presence of at least one of the referenced item.

What is claimed is:

1. A carbon nano-tube (CNT) composition, comprising:
a CNT; and
a metallic precursor capable of being transformed into a metal nanoparticle through a heat treatment.

2. The CNT composition of claim 1, further comprising a CNT dispersant.

3. The CNT composition of claim 1, wherein the metallic precursor is bonded onto the CNT surface.

4. The CNT composition of claim 1, wherein the metallic precursor contains at least one metallic element selected from the group consisting of Ag, Au, Cu, Pt and Pd.

5. The CNT composition of claim 1, wherein the heat-treatment is performed at a temperature lower than 200° C.

6. A CNT thin film, comprising:
a substrate; and
a CNT composition coated on the substrate, wherein the CNT composition includes a CNT; and a metallic particle distributed on the CNT surface.

7. The CNT thin film of claim 6, wherein the metallic particle includes a metallic nanoparticle.

8. The CNT thin film of claim 6, wherein the substrate includes a flexible transparent substrate.

9. The CNT thin film of claim 6, wherein the metallic particle is formed by heat-treating a metallic precursor having been adsorbed in the CNT surface.

10. The CNT thin film of claim 9, wherein the heat treatment is carried out at a temperature lower than 200° C.

11. The CNT thin film of claim 6, wherein the metallic particle contains at least one metallic element selected from the group consisting of Ag, Au, Cu, Pt and Pd.

12. A method of manufacturing a CNT thin film having metallic particles, comprising:
mixing a CNT with a CNT dispersant to form a CNT-dispersed solution;
forming a CNT thin film using the CNT-dispersed solution;
adding a metallic precursor to the CNT thin film; and
heating the CNT thin film and the metallic precursor to transform the metal precursor into a metallic particle.

13. The method of claim 12, wherein in adding the metallic precursor, the metallic precursor is adsorbed on the CNT thin film while a metallic precursor solution is filtered and allowed to pass through the CNT thin film.

14. The method of claim 12, wherein in adding the metallic precursor, the metallic precursor is adsorbed on the CNT thin film while the CNT thin film is immersed in a metallic precursor solution.

15. The method of claim 12, further comprising the step of:
transferring the CNT thin film onto a substrate.

16. The method of claim 15, wherein the substrate includes a flexible transparent substrate.

17. The method of claim 12, wherein the heat treatment is carried out at a temperature lower than 200° C.

18. The method of claim 12, wherein the metallic particle includes metallic nanoparticles.

19. The method of claim 18, wherein the metallic nanoparticles have a substantially uniform size.

20. The method of claim 12, wherein the metallic precursor contains at least one metallic element selected from the group consisting of Ag, Au, Cu, Pt and Pd.

21. A manufacturing method of a CNT thin film, comprising the steps of:
mixing a CNT, a solvent, and a metal precursor to prepare a CNT-metal precursor mixture;
forming a thin film in use of the CNT-metal precursor mixture; and
heating the thin film to distribute a metal nanoparticle on the thin film surface.

22. A CNT electrode comprising a CNT thin film according to claim 6.

23. A thin film transistor comprising a CNT thin film according to claim 6.

24. A thin film transistor having a CNT electrode of claim 22.
